(19) United States
(12) Patent Application Publication
(10) Pub. No.: US 2014/0082926 A1
(43) Pub. Date: Mar. 27, 2014

(54) CONFORMAL FIXTURE COVER

(71) Applicant: APPLE INC., Cupertino, CA (US)

(72) Inventors: Ching Yu John Tam, Cupertino, CA (US); Ching-Cheng Huang, Cupertino, CA (US); Xingqun Li, Cupertino, CA (US)

(73) Assignee: Apple Inc., Cupetino, CA (US)

(21) Appl. No.: 13/629,579

(22) Filed: Sep. 27, 2012

(51) Int. Cl. H05K 13/00; B25B 11/00

(52) U.S. Cl. 29/559; 29/760; 29/743; 220/240

(57) ABSTRACT

Embodiments described herein take the form of fixtures to be used in a manufacturing process. In particular, a manufacturing fixture may be sized to accept one or more electronic components, such as a printed circuit board (PCB) having various electrical elements. The PCB may be placed on the fixture in a predetermined area. The PCB may be placed in a depression or aperture sized to accept the PCB. When the PCB is placed within the fixture, a cover may be lowered or otherwise placed across the PCB in order to hold the PCB in place. The cover contacts the PCB and is pliable or malleable to conform to those portions of the PCB it contacts. When the cover is closed, a negative pressure may be induced in the fixture beneath the cover. When the PCB is held in position, the manufacturing fixture may operate on the PCB.

### TECHNICAL FIELD

Embodiments described herein relate generally to a fixture cover for a manufacturing process, and more particularly to a vacuum-sealed fixture cover.

### BACKGROUND

Many manufacturing processes require the devices being manufactured to be held securely in place in a very particular location. Some manufacturing fixtures, for example, include a receptacle in which a device must be positioned so that a manufacturing operation may be performed on the device. Misalignment of the device or motion of the device during the operation typically results in device destruction or inoperability.

In order to secure a device, such as a printed circuit board, in the fixture receptacle, a pneumatic press is often used. The press may take the form of a specially configured structure that is pneumatically lowered into the receptacle to secure the device. The structure may be tooled or otherwise shaped to match the contours of the printed circuit board and any electronic components attached thereto, for example. In this fashion, the pneumatic press may securely retain the printed circuit board so that the manufacturing process may be carried out.

Such presses, however, may be particularly expensive. The tooling and machining required to create the specially configured structure may be expensive. Likewise, the operation of the press is prone to failure as it is relatively mechanically complex, requiring multiple automated moving parts.

Further, the presses typically are configured only to operate with a particular type of printed circuit board at a particular stage of manufacture, as the specially configured surface must take into account the shape of the circuit board during the operation in question. Thus, the presses typically cannot be changed and have little flexibility to be used for other operations.

In addition, if the printed circuit board is even slightly misaligned, lowering the pneumatic press into the receptacle and onto the board may create a stress point on the board. Pressure from the press may thus be incorrectly distributed across the printed circuit board, often leading to cracking or breaking of the board. It will be readily appreciated that a cracked or broken printed circuit board is worthless and is generally discarded.

### SUMMARY

Certain embodiments described herein may take the form of a manufacturing apparatus, including: a manufacturing fixture; a receptacle defined on the manufacturing fixture; and a cover. In such embodiments, the cover may cooperate with the receptacle to encompass a device placed on the receptacle. Further, in such embodiments, the cover may include a top sheet that deforms upon contact with the device placed on the receptacle.

Still other embodiments may take the form of a cover for a manufacturing apparatus, including: a frame; and a flexible sheet affixed to the frame. In these embodiments, the frame may be configured to provide a seal for a receptacle of the manufacturing apparatus. In addition, the flexible sheet may be configured to deform when in contact with a device held in the receptacle.

Yet other embodiments may take the form of a method for performing a manufacturing operation on a device, including the operations of: placing the device within a receptacle defined in a manufacturing fixture, the placement facilitated by at least one alignment feature; closing a conformable cover over the receptacle, a flexible portion of the conformable cover contacting at least a portion of the device when the cover is closed and thereby deforming to accommodate the at least a portion of the device; applying a negative pressure within the receptacle, thereby maintaining a position of the device within the receptacle; and performing the manufacturing operation on the device while the position of the device is maintained by the negative pressure.

Embodiments will be more fully understood and appreciated upon reading the disclosure in its entirety.

### BRIEF DESCRIPTION OF THE FIGURES

FIG. 1 depicts a first embodiment of a manufacturing fixture having a conformal cover.

FIG. 2 depicts the fixture and cover of FIG. 1, with the cover closed.

FIG. 3 depicts an alternative embodiment of a fixture and conformal cover.

FIG. 4 depicts a top-down view of still another alternative embodiment of a fixture.

FIG. 5 depicts a perspective view of still another alternative embodiment of a cover, suitable for use with the fixture shown in FIG. 4.

FIG. 6 depicts a side view of the cover of FIG. 5.

### DETAILED DESCRIPTION

Generally, embodiments described herein take the form of fixtures to be used in a manufacturing process. In particular, a manufacturing fixture may be sized to accept one or more electronic components, such as a printed circuit board (PCB) having various electrical elements, such as integrated circuitry, processors, leads, buses, traces and the like formed thereon. The PCB may be placed on the fixture in a predetermined area. The PCB may be placed in a depression or aperture sized to accept the PCB. As another option, the PCB may be placed on a flat surface between one or more guide elements sized and shaped to indicate the proper placement of the PCB, and optionally to retain the PCB in place.

When the PCB is placed within the fixture, a cover may be lowered or otherwise placed across the PCB in order to hold the PCB in place. In some embodiments the cover may contact the PCB at least partially when closed, while in others the cover may not contact the PCB. Generally, if the cover contacts the PCB or is to contact it at some point, the contacting portion may be pliable or malleable to conform to those portions of the PCB it contacts.

When the cover is closed, a negative pressure may be induced in the fixture beneath the cover. One or more vacuum lines may be activated, for example. As described in further detail below, the cover may form an airtight or partially airtight seal with a contacted surface of the fixture, thereby facilitating the negative pressure acting on the PCB. The negative pressure, conformal cover, and/or guide elements may each be sufficient to maintain the PCB in place, or one or more of these may cooperate to maintain the PCB's position.

When the PCB is held in position, the manufacturing fixture may operate on the PCB. For example, one or more test pins or leads may rise from the fixture through one or more apertures to make contact with the PCB without having the PCB move. These test pins may be used to perform diagnostics on the PCB and/or associated circuitry. As another example, traces or connections may be soldered or deposited on the underside of the PCB (e.g., the side facing into the fixture). As still another option, one or more electrical components may be affixed to the board by the fixture, for example through the use of automated manufacturing techniques.

When the operations on the PCB are complete, the cover may be removed, retracted or the like, and the PCB removed from the fixture. Removal may be done by hand or in an automated fashion.

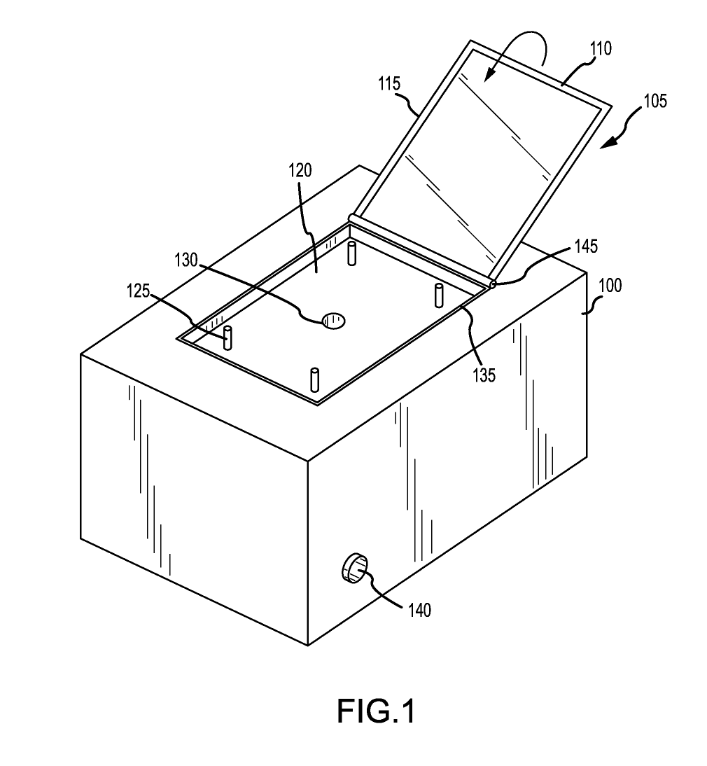

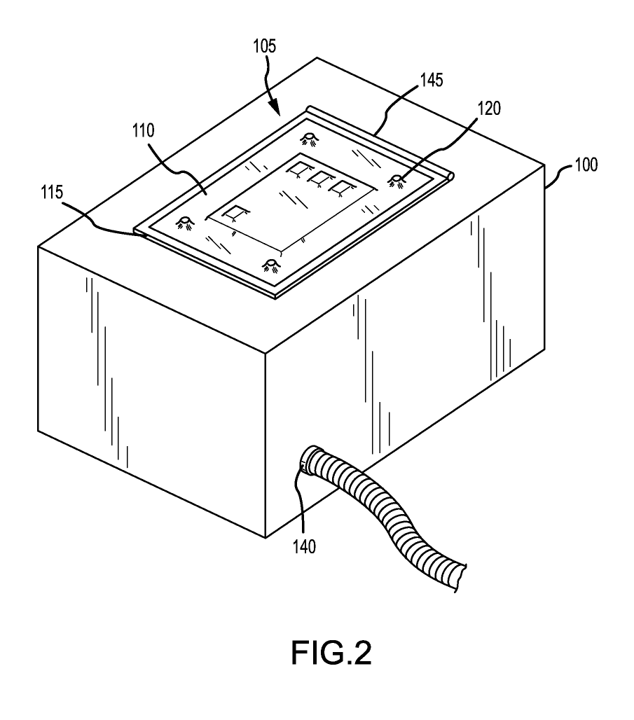

FIG. 1 generally depicts a first embodiment of a manufacturing fixture 100 having a conformal cover 105. The fixture 100 may have a receptacle 120 defined in a surface. The conformal cover 105, when closed (as discussed below and shown with respect to FIG. 2) fully overlays the receptacle 120.

The cover 105 includes a frame 115 that extends outwardly from atop sheet 110. A hinge 145 connects the cover 105 to the fixture 100. Some embodiments, as discussed later, may omit the hinge 145 and/or may not be connected to the fixture 100 when the fixture is not in operation.

The top sheet 110 may be made from a variety of materials. In the present embodiment, the sheet may be made from any sufficiently flexible or deformable material that permits stretching over raised portions of a PCB that is accepted in the receptacle 120 when the cover 105 is closed. Suitable materials include rubber, latex, polystyrene, polypropylene, nitrile, neoprene, and the like. A variety of different elastomers may function as the top sheet 110. The top sheet may be treated to reduce electrostatic discharge (ESD) or may be made from a material that is ESD-free. In such an embodiment, the top sheet generally will not discharge an electrostatic charge into the PCB when the two contact, thereby preventing or reducing the chance that the top sheet will inadvertently damage the PCB or components thereon. The top sheet may be made from a material that compresses, rather than stretches, when in contact with the PCB, as well.

In some embodiments, the top sheet 110 is transparent, as generally shown in FIG. 1. A transparent or semi-transparent top sheet 110 may permit a viewer to monitor the alignment and lack of motion of the PCB in the receptacle 120 during operation of the fixture 100. It should be appreciated that the top sheet 110 need not be transparent; in some embodiments, the top sheet may be opaque or translucent.

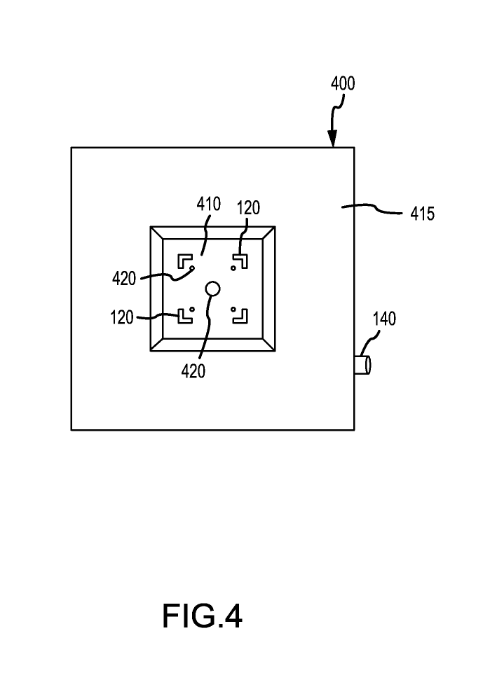

One or more alignment features 125 (also referred to as “guide elements”) may be present within the receptacle 120. These alignment features 125 may be formed as posts, as shown in FIG. 1, or may take a variety of other forms. For example, FIG. 4 shows the alignment features 125 as L-shaped, raised walls. Further, and as also shown in FIG. 4, not all alignment features need be the same shape, size and/or height. One of the L-shaped walls of FIG. 4 is longer than the others, as one example. Other embodiments may have alignment features formed in different shapes and/or cross-sections, such as square posts, grooved or flanged walls, and the like.

Returning to FIG. 1, a port 130 may also be defined in the receptacle 120. The port is operably connected to an outlet 140, which in turn may be connected to a hose or pipe that runs to a pump (not shown). Through operation of the pump, a negative pressure may be applied to the interior of the receptacle 120 when the conformal cover 105 is closed. The negative pressure may be generated by applying a vacuum or partial vacuum to the interior of the receptacle, by drawing air through the port 130 and out the outlet 140 as the pump operates. In some embodiments, the port 130 may be connected directly to a pump housed in the internals of the fixture, such that outlet 140 may not be necessary.

Operation of the fixture 100 and conformal cover 105 will now be discussed. Generally, a PCB may be placed within the receptacle 120, either manually or through an automated system. The guide elements 125 facilitate proper alignment and placement of the PCB. The guide elements 125 may be configured to ensure the PCB may only fit within the receptacle 120 in a single orientation, for example, and/or only with the proper side facing up.

Once the PCB is inside the receptacle 120, the conformal cover 105 may be closed over the receptacle. Generally, the receptacle 120 is designed so that at least some components or elements affixed to the PCB project above the top surface of the fixture 100 (e.g., past a plane defined by the top of the walls of the receptacle, including the lip 135 discussed below). Thus, when the conformal cover 105 is closed, the top sheet 110 contacts at least the aforementioned components. The top sheet 110 may either deform or compress about the components of the PCB as it closes.

The frame 115 of the conformal cover 105 may be sized to fit snugly around a lip 135 projecting upward from the sidewalls of the receptacle 120. A groove, detent or other mating surface may be defined in the interior of the frame 115 walls. This mating surface may cooperate with a complementary mating surface formed in the outer sidewalls of the lip 135 to retain the conformal cover 105 in a closed position. Certain embodiments may omit the mating surfaces on both frame 115 and lip 135; instead, a hook, latch or other retaining device may be used to keep the conformal cover 105 closed. In still other embodiments, friction between the frame and lip may be sufficient to keep the cover closed.

When the cover 105 is closed and (optionally) secured, as shown in FIG. 2, negative pressure may be induced in the receptacle 120. Air may flow from the receptacle 120, through the port 130 (depicted in FIG. 1) and out the outlet 140. A hose 200 is shown in FIG. 2 connected to the outlet 140. The hose may be connected to a pump (not shown) to induce negative pressure.

The negative pressure in the receptacle generally is no more than 14 pounds per square inch (PSI), which is the pressure of a perfect vacuum. A perfect vacuum need not be induced in the receptacle 120. Rather, all that is necessary is sufficient negative pressure to prevent the PCB from moving during operation of the fixture 100. In some embodiments, 1-2 PSI, or even less (on the order of fractional PSI), may be sufficient to ground the PCB and prevent motion during fixture operation. The downward force exerted on the PCB by the negative pressure generally prevents the PCB from moving within the receptacle. The alignment features 125 may likewise aid in restricting PCB motion, as may a downward force exerted on the PCB by the top sheet 110 when the conformal cover 105 is closed. In certain embodiments, the conformal cover 105 alone may be sufficient to immobilize the PCB during fixture operation, so that no negative pressure is needed. In those embodiments, the port 130 and/or outlet 140 may be omitted.

Once the PCB is stabilized through the action of the port 130 and/or conformal cover 105, the fixture 100 may operate on the PCB. Instrumentation, test leads, manufacturing tools, and/or other operational features may extend from an interior of the fixture through one or more access ports (not shown). Alternately, components on the bottom side of the PCB (with reference to its mounting in the fixture 100) may project through one or more access ports into the fixture interior, where they may interface with the instrumentation/leads/tools. In one embodiment, test pins may connect or touch electrically conductive pads, pin-outs or the like on the PCB. The test pins may facilitate an electrical connection between the PCB and testing machinery, thereby permitting the PCB and its associated circuitry to undergo diagnostic evaluation.

When the operation of the fixture 100 with respect to the PCB is complete, the negative pressure may be terminated and the conformal cover 105 removed from its position over the receptacle 120. The PCB may then be removed from the receptacle.

It should be appreciated that the conformal cover 105 is relatively simple to use and may be deployed rapidly, especially with respect to certain prior art machinery that used a pneumatic press to hold the PCB in place. This, in turn, permits quicker manufacturing operations to take place on the PCB, thereby increasing the number of parts that may be subjected to any given manufacturing process in any given period of time. Thus, efficiencies may be realized through use of embodiments described herein.

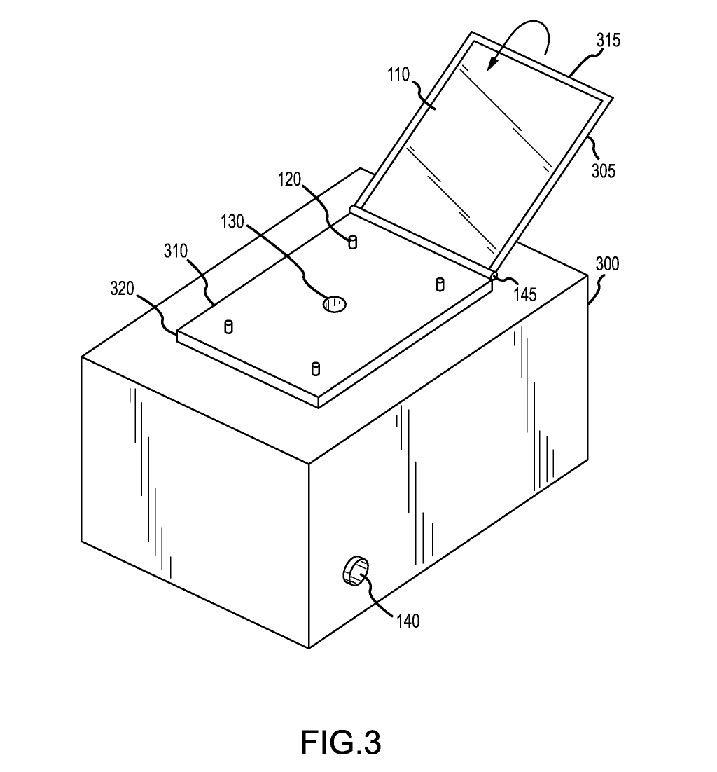

FIG. 3 depicts an alternative embodiment of a fixture 300 and conformal cover 305. Here, the fixture 300 has a raised platform 310 in place of the recessed receptacle 120 of FIG. 1. The raised platform 300 includes one or more alignment features 120 and a port 130, both of which function generally as described above with respect to FIG. 1. The fixture 100 likewise includes an outlet 140. The platform may be considered a type of receptacle, insofar as it accepts a PCB and facilitates properly aligning it for the fixture to operate on the PCB.

The conformal cover 305, in this embodiment, lacks a full frame 115 extending outwardly from the top sheet 110. Instead, the cover 305 has a single sidewall 315 designed to mate with a complementary platform surface 320. When the cover is closed, the cover sidewall 315 may snap-fit or friction fit against the platform surface 320, thereby holding the cover in place and pressing the PCB downward against the platform 310. In some embodiments, one or more supports (not shown) may extend from the hinge 145 to the cover sidewall 315 to impart rigidity to the cover 305. In other embodiments, a latch, detent, groove or other mating structure may be formed on one of the cover sidewall 315 and platform surface 320, which a complementary mating structure formed on the other.

In operation, the conformal cover 305 shown in FIG. 3 operates in the same or a similar fashion as the conformal cover 105 described above with respect to FIGS. 1 and 2.

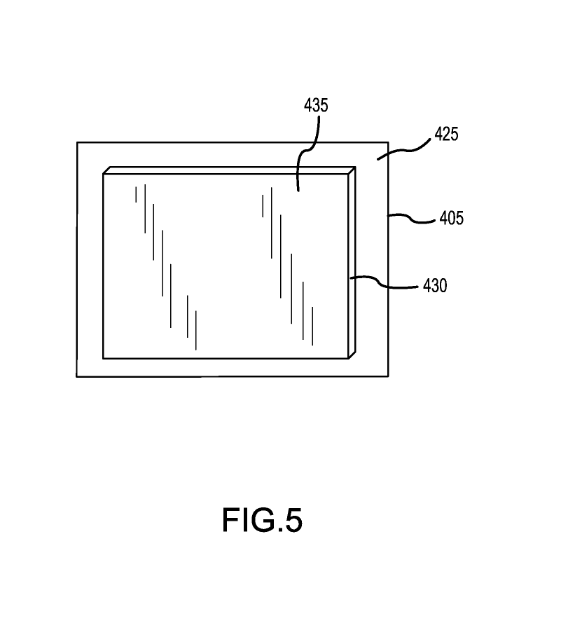

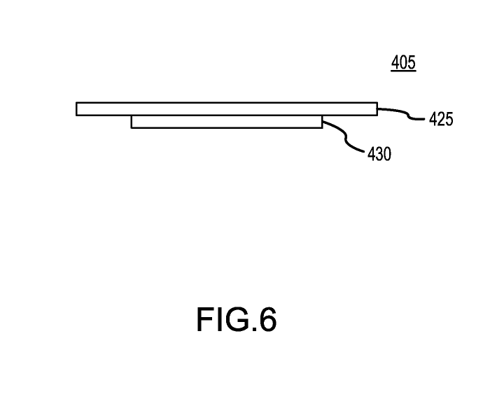

FIG. 4 is a top-down view of yet another embodiment of a fixture 400, while FIGS. 5 and 6 depicts isometric and side views of a conformal cover 405 suitable for use with the fixture. This manufacturing fixture 400 has a receptacle 410 defined in its top surface 415. One or more alignment features 120 may be present within the receptacle 410. As shown in FIG. 4, the alignment features may be of a variety of shapes and sizes and need to be identical to one another. As with other embodiments described herein, the alignment features generally serve to orient and, optionally, retain the PCB within the receptacle 410.

The receptacle also has a number of ports 420 defined in its base. The ports 420 function in a fashion similar to the ports 130 discussed with respect to prior embodiments. The ports 420 of FIG. 4 illustrate that multiple ports may be used to induce a negative pressure within the receptacle and on a PCB or other retained device in the receptacle, and that the ports need not be of uniform size and/or shape. Ports may be located in the receptacle base at particular points where negative pressure against the PCB should be ensured in order to permit the fixture 400 to perform its operations on the PCB. Generally, it should be appreciated that in an air tight or partially air tight receptacle (e.g., the receptacle 410 with the cover 405 installed), the negative pressure may essentially equalize throughout the receptacle. Nonetheless, proper positioning of the ports 420 may reduce the likelihood of any pressure variance through the receptacle 410.

The ports 420 may be operably connected to an outlet 140 to permit air to be drawn through the ports and outlet by an attached pump, as previously described.

Turning now to FIGS. 5 and 6, the conformal cover 405 will be discussed. This cover 405 may include a top plate 425, a frame 430 extending downwardly from the top plate, and a base sheet 435 affixed to the frame. The base sheet 435 is similar to the top sheet 110 discussed with respect to FIGS. 1 and 2, but here is positioned at the bottom of the conformal cover 405. The base sheet may be made from any material discussed herein with respect to the top sheet 110, and generally stretches and/or deforms when in contact with a PCB held in the receptacle 410, in a manner similar to the top sheet of earlier figures. In some embodiments, the base sheet may be replaced by a top sheet positioned within the top plate 425.

As can be appreciated from the views of FIGS. 5 and 6, the conformal cover 405 may be plug-shaped, such that the bottom sheet 435 is pressed into the receptacle 410 and contacts a PCB or other device held therein. The top plate 425 may extend past the edges of the receptacle 425 and overlay a portion of the top surface of the fixture 400, although in some embodiments the top plate 425 may be omitted. The top plate and frame 430 may cooperate with the sidewalls of the receptacle 420 to create an air tight or partly air tight seal within the receptacle when the conformal cover 405 is placed on the fixture.

As can be appreciated by viewing the conformal cover 405 of FIGS. 5 and 6, the cover need not be affixed or attached to the fixture 400 when it is not in use. For example, unlike the cover 105 shown in FIGS. 1 and 2 or the cover 315 of FIG. 4, this cover 405 is not hingedly affixed to the fixture but is completely separate.

In yet another embodiment of a conformal cover, or in accordance with any of the embodiments discussed herein, the cover may not directly contact the PCB when the cover is closed over the receptacle. Rather, the cover may be sucked downward onto the PCB (or a portion thereof) when the negative pressure is applied.

As still another option, a conformal cover may be rolled on a central spindle and pulled across the receptacle to a latching mechanism, rather than being hingedly attached to the fixture or a completely separate element.

It should be appreciate that the embodiments discussed herein may simplify certain manufacturing processes. As previously mentioned, many manufacturing and or testing procedures employ a pneumatically-activated top press that descends onto (or near to) the fixture in order to fix the PCB in position with respect to the fixture. Given the precision required in many modern manufacturing and/or testing operations, use of a pneumatic press may be time-consuming and difficult. The relative ease and simplicity of embodiments discussed herein facilitate faster and simpler manufacturing and testing.

Further, since the conformal cover stretches or deforms to accommodate the device in the receptacle, pressure may be applied relatively evenly over the device, thereby reducing the likelihood that a stress point may be present on the device during manufacturing operations. Reducing stress points in this fashion may lead to fewer devices breaking or failing during operation of the fixture.

In addition, since the fixture itself is stationary and the conformal cover is often positionally fixed with respect to the fixture, the relative tolerances of the device, the receptacle, and the tools required for manufacturing operations are relatively easy to control. The lack of a moving press may provide better control of tight tolerances.

Although embodiments herein have been discussed with respect to a fixture operating on a PCB, it should be appreciated that substantially any device or item being manufactured may be used with a fixture having a conformal cover. For example, certain toys, appliances, and the like may be used instead of a PCB. In addition, although the discussion herein has been with respect to certain physical structures and methods of operation, various embodiments may add, omit or otherwise alter structures and/or methods and nonetheless be embraced by the disclosed concepts. Accordingly, the proper scope of protection is set out by the appended claims.

We claim:

1. A manufacturing apparatus, comprising:
a manufacturing fixture;
a receptacle defined on the manufacturing fixture; and
a cover, the cover cooperating with the receptacle to encompass a device placed on the receptacle; wherein
the cover comprises a top sheet that deforms upon contact with the device placed on the receptacle.

2. The manufacturing apparatus of claim 1, further comprising at least one port defined in the manufacturing fixture, the port applying a negative pressure to the device placed on the receptacle when the manufacturing fixture operates.

3. The manufacturing apparatus of claim 2, wherein the top sheet is formed from a compressible material.

4. The manufacturing apparatus of claim 2, wherein the top sheet is formed from a flexible material.

5. The manufacturing apparatus of claim 4, wherein the top sheet is formed from a material treated to resist electrostatic discharge.

6. The manufacturing apparatus of claim 4, wherein the top sheet is transparent or semi-transparent.

7. The manufacturing apparatus of claim 4, wherein:
the fixture further comprises a set of joined sidewalls extending upwardly about the receptacle;
the cover further comprises a frame fitting about the set of joined sidewalls when the cover is closed; and
the cover creates a seal for the receptacle when closed.

8. The manufacturing apparatus of claim 7, wherein the seal is not air tight.

9. The manufacturing apparatus of claim 7, wherein the device is held in place by the negative pressure during operation of the fixture.

10. The manufacturing apparatus of claim 7, wherein the receptacle extends into the fixture.

11. The manufacturing apparatus of claim 4, wherein:
the fixture further comprises a set of joined sidewalls extending upwardly about the receptacle;
the cover further comprises a lip that is positioned adjacent to at least one of the set of joined sidewalls when the cover is closed; and
the cover creates a seal for the receptacle when closed.

12. The manufacturing apparatus of claim 11, wherein the lip is friction-fitted to the at least one of the set of joined sidewalls when the cover is closed.

13. The manufacturing apparatus of claim 11, further comprising at least one alignment feature defined on the receptacle.

14. The manufacturing apparatus of claim 13, further comprising at least a second alignment feature defined on the receptacle, the at least one alignment feature and at least a second alignment feature varying from one another in shape.

15. The manufacturing apparatus of claim 2, wherein the cover is hingedly attached to the fixture.

16. A cover for a manufacturing apparatus, comprising:
a frame; and
a flexible sheet affixed to the frame; wherein
the frame is configured to provide a seal for a receptacle of the manufacturing apparatus; and
the flexible sheet is configured to deform when in contact with a device held in the receptacle.

17. The cover of claim 16, wherein the frame extends downwardly on all sides from the flexible sheet.

18. The cover of claim 16, wherein the frame comprises:
a first side extending downwardly from the flexible sheet; and
a plurality of supports affixed to the first side and the flexible sheet, the plurality of supports providing rigidity to the cover.

19. The cover of claim 18, wherein the first side is accepted within the receptacle.

20. The cover of claim 16, further comprising:
a top plate to which the frame is affixed; wherein
the top plate defines a top surface of the frame.

21. The cover of claim 20, wherein the flexible sheet defines a bottom surface of the frame.

22. The cover of claim 20, wherein the flexible sheet is positioned within the top plate.

23. A method for performing a manufacturing operation on a device, comprising the operations of:
placing the device within a receptacle defined in a manufacturing fixture, the placement facilitated by at least one alignment feature;
closing a conformable cover over the receptacle, a flexible portion of the conformable cover contacting at least a portion of the device when the cover is closed and thereby deforming to accommodate the at least a portion of the device;
applying a negative pressure within the receptacle, thereby maintaining a position of the device within the receptacle; and
performing the manufacturing operation on the device while the position of the device is maintained by the negative pressure.

24. The method for performing a manufacturing operation on a device of claim 23, wherein the manufacturing operation comprises connecting at least one test element to a connection on the device.
